(19) United States
(12) Patent Application Publication
(10) Pub. No.: US 2026/0344511 A1
(43) Pub. Date: Oct. 29, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Cheng-Hsiang HSU, Kaohsiung (TW); Hsin-Hua HUANG, Kaohsiung (TW); Hung-I LIN, Kaohsiung (TW); Chi Hao CHIANG, Kaohsiung (TW); Hsin-Chin CHANG, Kaohsiung (TW)

(73) Assignee: Advanced Semiconductor Engineering, Inc., Kaohsiung (TW)

(21) Appl. No.: 19/189,208

(22) Filed: Apr. 24, 2025

(51) Int. Cl. H10W 90/00; H10W 70/60; H10W 76/153

(52) U.S. Cl. CPC H10W 90/00; H10W 70/611; H10W 76/153; H10W 90/401

(57) ABSTRACT

The present disclosure provides an electronic device. The electronic device includes a standoff structure, a first component, a second component, and an interposer. The standoff structure defines a space. The first component is disposed within the space. The second component is disposed over the standoff structure. The interposer is disposed between the second component and the standoff structure.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes a first carrier, a first converter, a first capacitor, and a second carrier. The first converter is supported by the first carrier. The first capacitor is supported by the first carrier and configured to transceive a first voltage between the first carrier and the first converter. The second carrier is stacked on the first carrier and configured to receive a second voltage, different from the first voltage, from the first converter.

In some arrangements, an electronic device includes a power unit, a first capacitor, and a second capacitor. The first capacitor is configured to transmit a first voltage to the power unit. The second capacitor abuts the first capacitor and is configured to transmit a second voltage, different from the first voltage, to a computing unit. The first capacitor is closer to the power unit than to the computing unit, and the second capacitor is closer to the computing unit than to the power unit.

In some arrangements, an electronic device includes a first carrier, a converter, and an input capacitor. The converter is disposed over the first carrier. The input capacitor is disposed under the first carrier and electrically connected to the converter. The input capacitor is configured to provide an electrical path conducting a power to the converter without passing through the second carrier.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device, in accordance with some arrangements of the present disclosure.

FIG. 2 illustrates an enlarged view of the electronic device as shown in FIG. 1, in accordance with some arrangements of the present disclosure.

FIG. 3 illustrates a cross-sectional view of an electronic device, in accordance with some arrangements of the present disclosure.

FIG. 4 illustrates a cross-sectional view of an electronic device, in accordance with some arrangements of the present disclosure.

FIG. 5 illustrates a cross-sectional view of an electronic device, in accordance with some arrangements of the present disclosure.

FIG. 6 illustrates a cross-sectional view of an electronic device, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

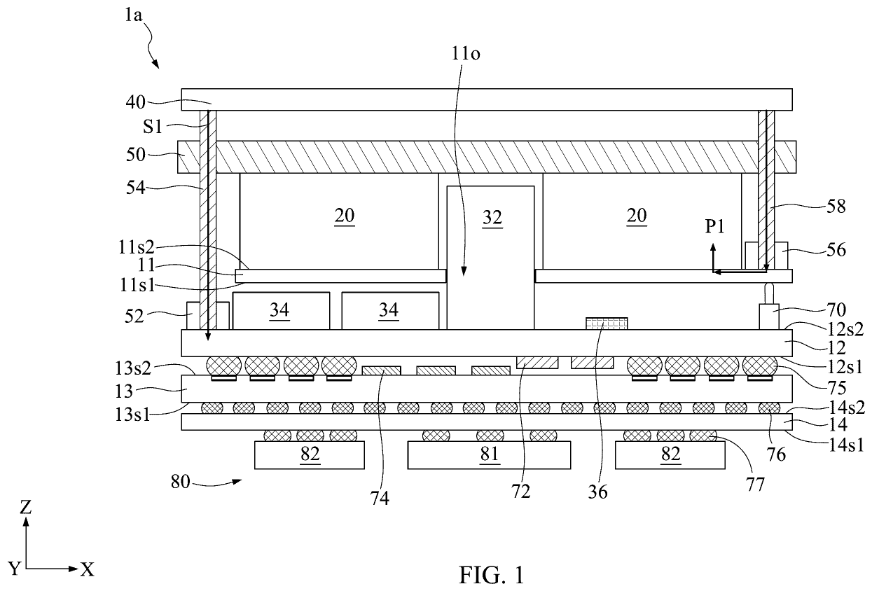

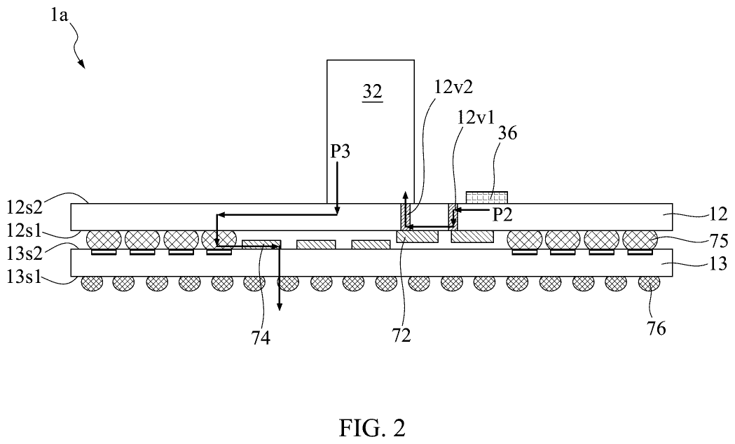

FIGS. 1 and 2A-2C illustrate an electronic device 1a, in accordance with some arrangements of the present disclosure. In some arrangements, the electronic device 1a may include carriers 11, 12, and 13, electronic components 20, 32, 34, and 36, a circuit structure 40, and a heat dissipating structure 50.

As shown in FIGS. 1 and 2A, each of the carriers 11, 12, and 13 may be formed as a printed circuit board (PCB), flexible printed circuit board (FPCB), lead frame, a combination thereof, or other suitable circuit structures. The carriers 11, 12, and 13 may be at different levels (or elevation or height) along the Z direction. Each of the carriers 11, 12, and 13 may include multiple metal layers separated from one another by layers of dielectric material and interconnected by electrically conductive vias. In some embodiments, each of the carriers 11, 12, and 13 may be formed of an epoxy resin, a fiberglass-reinforced epoxy resin, an epoxy resin with inorganic fillers, a ceramic material, or a polymer material such as polyimide. The carrier 11 may have a surface 11s1 (or lower surface) and a surface 11s2 (or upper surface) opposite to the surface 11s1. The carrier 12 may have a surface 12s1 (or lower surface) and a surface 12s2 (or upper surface) opposite to the surface 12s1. The carrier 11 may be disposed over the surface 12s2 of the carrier 12. The carrier 12 may be disposed under the carrier 11. In some arrangements, the carrier 11 may have a dimension (e.g., surface area along the XY plane) less than that of the carrier 12. In some arrangements, a portion of the surface 12s2 of the carrier 12 may be exposed by the carrier 11. The carrier 13 may have a surface 13s1 (or lower surface) and a surface 13s2 (or upper surface) opposite to the surface 13s1. The surface 13s2 of the carrier 13 may face the carrier 12. In some arrangements, the carrier 12 may also be referred to as the carrier A, and the carrier 13 may also be referred to as the carrier B.

The electronic component 20 may be disposed on or over the surface 11s2 of the carrier 11. In some arrangements, the electronic component 20 may function as a first stage power module (or first power conversion stage or converter or electrical converter or power unit). In some arrangements, the electronic component 20 may be configured to convert a higher voltage (e.g., 48 V) to a lower voltage (e.g., 12 V). For example, the electronic component 20 may be configured to receive a higher voltage from the circuit structure 40 and transmit a lower voltage to the electronic component 32 (or electronic component 34). In some arrangements, the electronic component 20 may include at least one power module (or converter), which includes a transistor(s), a diode(s), a capacitor(s), an inductor(s), and/or other suitable elements. For example, the electronic component 20 may include a circuit structure formed as a PCB, FPCB, or other suitable circuit structures. The active components (e.g., converters, controllers, and/or drivers) and passive components (e.g., capacitors and/or inductors) may be disposed on the circuit structure.

The electronic components 32 and 34 may be disposed on or over the surface 12s2 of the carrier 12. Each of the electronic components 32 and 34 may function as a second stage power module (or second power conversion stage or converter or electrical converter or power unit). In some arrangements, each of the electronic components 32 and 34 may be configured to convert a higher voltage (e.g., 12 V) to a lower voltage (e.g., 8 V, 6 V, 4 V, 2 V, or less). In some arrangements, the electronic components 32 and 34 may have different thicknesses along the Z direction. The electronic components 32 and 34 may be electrically connected to the carrier 11. The electronic components 32 and 34 may be electrically connected to the carrier 12. The electronic components 32 and 34 may include multiple elements on a circuit structure (e.g., PCB). For example, the electronic components 32 and 34 may include a transistor(s), a controller(s), and a passive element(s). The electronic components 32 and 34 may include multiple elements on a circuit structure (e.g., PCB). For example, the electronic components 32 and 34 may include a transistor(s), a controller(s), and a passive element(s). In some arrangements, each of the electronic components 32 and 34 may also be referred to as a voltage regulator or power block.

In some arrangements, the electronic component 32 may be partially disposed within an opening 11o defined by the carrier 11. In some arrangements, a portion of the electronic component 32 may be protruded from the surface 11s2 of the carrier 11. In some arrangements, the thickness (e.g., the length along the Z direction) of the electronic component 32 may be greater than that of the electronic component 20. The electronic component 34 may be disposed within a space defined by the carriers 11 and 12. In some arrangements, the electronic component 34 may have a thickness (e.g., the length along the Z direction) less than that of the electronic component 20. In some arrangements, the thickness of the electronic component 32 may be greater than or equal to 7 mm, such as 7 mm, 8 mm, 9 mm, 10 mm, or more. In some arrangements, the thickness of the electronic component 20 may range between 3 mm and 7 mm, such as 3 mm, 4 mm, 5 mm, 6 mm, or 7 mm. The thickness of the electronic component 34 may range between about 1 mm and 5 mm, such as 1 mm, 2 mm, 3 mm, 4 mm, or 5 mm.

In some arrangements, the electronic component 36 may be disposed on or over the surface 12s2 of the carrier 12. In some arrangements, the electronic component 36 may function as a controller that is configured to turn on or turn off the electronic component 32 (or electronic component 34). In some arrangements, the electronic component 36 may be configured to control or adjust the output of the electronic component 32 (or electronic component 34). In some arrangements, the electronic component 36 may have a dimension (e.g., volume or thickness) less than a dimension of the electronic components 32 and 34. It should be noted that the electronic device 1a may include more components between the carriers 11 and 12. In certain configurations, the surface 12s2 of the carrier 12 may be designed to house converters or controllers optimized for high-speed calculations. Consequently, additional components, such as passive devices, are positioned beneath the carrier 12 to fulfill the demands of high-speed processing.

In some arrangements, the circuit structure 40 (or power delivery board) may be disposed on or over the surface 11s2 of the carrier 11. In some arrangements, the circuit structure 40 may be configured to provide the electronic component 20 with a relatively great power (e.g., 48 V). In some arrangements, the circuit structure 40 may be configured to transmit a signal (e.g., non-power signal or data signal) to the carrier 12. In some arrangements, the circuit structure 40 may include a PCB, FPCB, or other suitable circuit structures. One or more electronic components (not shown) may be disposed on or over the circuit structure 40. For example, the electronic device 1a may include a power management integrated circuit (PMIC) die on or within the circuit structure 40. In this disclosure, the circuit structure 40 may also be referred to as an external device.

In some arrangements, the heat dissipating structure 50 may be disposed between the electronic component 20 and the circuit structure 40. In some arrangements, the heat dissipating structure 50 may be thermally coupled to the electronic component 20. For example, the heat dissipating structure 50 may be configured to transmit heat from the electronic component 20. In some arrangements, the heat dissipating structure 50 may be thermally coupled to the circuit structure 40. For example, the heat dissipating structure 50 may be configured to transmit heat from the circuit structure 40. In some arrangements, the heat dissipating structure 50 may be in contact with the electronic component 20. In some arrangements, the heat dissipating structure 50 may be spaced apart from the electronic component 20 by a thermal interface material (TIM) or adhesive. The heat dissipating structure 50 may include a cold plate, which may include a vapor chamber, heat pipe, and/or other suitable elements. The heat dissipating structure 50 may include thermal conductive materials, such as aluminum (Al), copper (Cu), chromium (Cr), tin (Sn), gold (Au), silver (Ag), nickel (Ni) or stainless steel, or a mixture, an alloy, or other combinations thereof.

In some arrangements, the electronic device 1a may include a connector 52 and conductive elements 54. The connector 52 may be disposed on or over surface 12s2 of the carrier 12. In some arrangements, the connector 52 may be configured to connect, hold, or accommodate the conductive elements 54. For example, the connector 52 may define a recess for accommodating a portion of the conductive elements 54.

The conductive elements 54 may be connected between the carrier 12 and the circuit structure 40. The conductive elements 54 may be disposed on or over the surface 12s2 of the carrier 12. In some arrangements, the conductive elements 54 may be configured to transmit a signal between the carrier 12 and the circuit structure 40. In some arrangements, the conductive elements 54 may penetrate the heat dissipating structure 50. In some arrangements, the conductive elements 54 may include a pogo pin, conductive pillar, or other suitable conductive elements. The conductive elements 54 may be configured to provide an electrical path (or signal path) conducting a signal S1 from the circuit structure 40 to the carrier 12.

The electronic device 1a may include a connector 56 and conductive elements 58. In some arrangements, the connector 56 may be disposed on or over the surface 11s2 of the carrier 11. In some arrangements, the connector 56 may be configured to connect, hold, or accommodate the conductive elements 58. For example, the connector 56 may define a recess for accommodating a portion of the conductive elements 58. In some arrangements, the conductive elements 58 may be connected between the carrier 11 and the circuit structure 40. The conductive elements 58 may be disposed on or over the surface 11s2 of the carrier 11. In some arrangements, the conductive elements 58 may be configured to transmit power (or power signal) between the electronic component 20 and circuit structure 40. For example, the conductive elements 58 may be configured to transmit a relatively great power (e.g., 48 V) from the circuit structure 40 to the electronic component 20. In some arrangements, the conductive elements 58 may penetrate the heat dissipating structure 50. In some arrangements, the conductive elements 58 may include a pogo pin, conductive pillar, or other suitable conductive elements. The circuit structure 40 may be configured to provide the electrical path (or power path) conducting power P1 (e.g., 48V) to the electronic component 20 through the conductive elements 58 and carrier 11. In some arrangements, the connector 52 may have a level (or height or elevation) less than that of the connector 56 with respect to the surface 12s2 of the carrier 12.

In some arrangements, the electronic device 1a may include electrical connections 70. In some arrangements, the electrical connections 70 may be disposed on or over the surface 12s2 of the carrier 12. The electrical connections 70 may be disposed at a peripheral region of the carrier 12. For example, the electrical connections 70 may surround the electronic components 32 and 34. The electrical connections 70 may be disposed between the carriers 11 and 12. In some arrangements, the electrical connections 70 may be configured to support the carrier 11. In some arrangements, the electrical connections 70 may electrically connect the carriers 11 and 12. In some arrangements, the electrical connections 70 may be configured to transmit power and/or signal. In some arrangements, the electrical connections 70 may include a pogo pin, conductive pillar, or other suitable conductive elements. In other arrangements, the electrical connections 70 may be replaced by an interposer(s), which may include a substrate (e.g., silicon substrate or other substrate) and conductive elements (e.g., through silicon via (TSV)) in the substrate. In other arrangements, the electrical connections 70 may be replaced by other conductive components, such as solder materials.

The electronic device 1a may include electrical connectors 75. The electrical connectors 75 may be disposed between the carriers 12 and 13. The electrical connectors 75 may be or include electrical contacts, such as solder balls (e.g., controlled collapse chip connection (C4) bumps, a ball grid array (BGA), a land grid array (LGA)), conductive bumps, or the like. The electrical connectors 75 may include alloys of gold and tin solder or alloys of silver and tin solder, or other suitable materials.

In some arrangements, the electronic device 1a may include passive devices 72. The passive devices 72 may be disposed under or mounted on the surface 12s1 of the carrier 12. In some arrangements, the passive devices 72 may be supported by or in direct contact with the surface 12s1 of the carrier 12. In some arrangements, the passive devices 72 may be disposed between the carriers 12 and 13. In some arrangements, the passive devices 72 may be spaced apart from the carrier 13. The passive devices 72 may include input capacitors (Cin) through which the power flows before being delivered to the electronic component 32 (or electronic component 34). In some arrangements, at least a portion of the passive devices 72 may be vertically overlap the electronic component 32 for a relatively short transmission path.

In some arrangements, the electronic device 1a may include passive devices 74. The passive devices 74 may be disposed under or mounted on the surface 13s2 of the carrier 13. In some arrangements, the passive devices 74 may be supported by or in direct contact with the surface 13s2 of the carrier 13. In some arrangements, the passive devices 74 may be disposed between the carriers 12 and 13. In some arrangements, the passive devices 74 may be spaced apart from the carrier 12. In some arrangements, the passive devices 74 may include output capacitors (Cout) through which the power flows after being transmitted from the electronic component 32 (or electronic component 34).

In some arrangements, the passive devices 74 may laterally overlap the passive devices 72 or overlap the passive devices 72 along the XY plane. In some arrangements, the passive device 72 may be closer to the electronic component 32 (or electronic component 34) than the passive device 74 is. In some arrangements, the level (or elevation) of the passive device 72 may be less than that of the passive device 74 with respect to the surface 12s1 of the carrier 12. In some arrangements, the passive devices 72 may have a capacitance greater than that of the passive devices 74, which may be due to the relatively high current that passes through the passive devices 72. In some arrangements, the passive devices 72 may have a dimension (e.g., volume or thickness) greater than that of the passive devices 74.

Please refer to FIG. 2, the carrier 12 may include conductive elements 12v1 and 12v2. Each of the conductive elements 12v1 and 12v2 may be configured to transmit power (or power signal) from the electronic component 36 (or the electronic component 20) to the electronic component 32. Each of the conductive elements 12v1 and 12v2 may include a via extending between the surface 12s1 and surface 12s2 of the carrier 12. The conductive elements 12v1 and 12v2 may be a part of a redistribution structure that includes multiple traces, vias embedded within dielectric materials (e.g., polyimide). The passive devices 72 may be electrically connected to the conductive elements 12v1 and 12v2. The passive devices 72 may be electrically connected between the electronic components 32 and 36. In some arrangements, at least a portion of the conductive elements 12v1 and 12v2 may vertically overlap the electronic component 32.

As shown in FIG. 2, the conductive elements 12v1 and 12v2 may be configured to provide an electrical path conducting power P2 (e.g., 12 V), from the electronic component 20 as shown in FIG. 1, to the electronic component 32. The electronic component 36 may be configured to provide an electrical path conducting power P2 to the electronic component 32. The passive devices 72 may be configured to provide an electrical path conducting power P2 to the electronic component 32. In some arrangements, the passive devices 74 may be configured to receive power P3 (e.g., 8 V, 6 V, 4 V, 2 V, or less) from the electronic component 32 through the carrier 12, electrical connectors 75, and carrier 13.

Please refer back to FIG. 1, the electronic device 1a may include a carrier 14 (or substrate). In some arrangements, the carrier 14 may be disposed on or under the surface 13s1 of the carrier 13. In some arrangements, the carrier 14 may include a semiconductor substrate, such as silicon, germanium, and other group III-V and group IV materials. The carrier 14 may include metal lines and vias, including but not limited to through-silicon vias (TSVs) for interconnection. In some arrangements, the carrier 14 may include a wafer, a panel form or other suitable forms. The carrier 14 may have a surface 14s1 (or a lower surface) and a surface 14s2 (or an upper surface) opposite to the surface 14s1.

The carrier 14 may be electrically connected to the carrier 13 through electrical connectors 76. The carrier 14 may be configured to support the operating module 80. In some arrangements, the electrical connectors 76 may include a reflowable material. The electrical connectors 76 may be or include electrical contacts, such as solder balls (e.g., controlled collapse chip connection (C4) bumps, a ball grid array (BGA), a land grid array (LGA)), conductive bumps, or the like. The electrical connectors 76 may include alloys of gold and tin solder or alloys of silver and tin solder, or other suitable materials.

In some arrangements, the operating module 80 (or computing unit) may be disposed on or under the surface 14s1 of the carrier 14. In some arrangements, the operating module 80 may be configured to generate non-power signals, such as analog signals, digital signals, clock signals, or other electrical signals. The operating module 80 may include electronic components 81 and 82. In some arrangements, the electronic components 81 and 82 may be disposed on or under the surface 14s1 of the carrier 14. In some arrangements, the electronic component 81 may include a processor or other suitable components. In some arrangements, the electronic component 81 may include an active device, such as a central processing unit (CPU), a microprocessor unit (MPU), a graphics processing unit (GPU), a microcontroller unit (MCU), a radio frequency integrated circuit (RFIC), an application-specific IC (ASIC), a field-programmable gate array (FPGA), or another type of IC. In some arrangements, the electronic component 82 may include a data storage unit or other suitable components. The electronic component 82 may be electrically connected to the electronic component 81 through the carrier 14. The electronic component 82 may be disposed on or under the surface 14s1 of the carrier 14. In some arrangements, the electronic component 82 may be configured to store the signals from the electronic component 81 and/or other devices. In some arrangements, the electronic component 82 may include a high band memory (HBM) die, dynamic random access memory (DRAM) die, static random access memory (SRAM) die, or other suitable memory devices. In some arrangements, the operating module 80 may further include other components, such as input/output dies configured to receive regulated power from the electronic component 32 (or electronic component 34) and/or transmit a processed signal to other devices (not shown). The electronic components 81 and 82 may be electrically connected to the carrier 14 by electrical connectors 77. In some arrangements, the electrical connectors 77 may include a reflowable material. The electrical connectors 77 may be or include electrical contacts, such as solder balls (e.g., controlled collapse chip connection (C4) bumps, a ball grid array (BGA), a land grid array (LGA)), conductive bumps, or the like. The electrical connectors 77 may include alloys of gold and tin solder or alloys of silver and tin solder, or other suitable materials. In other arrangements, the electronic components 81 and 82 may be electrically connected to the carrier 14 by hybrid-bond techniques, which involve a bonding between metallic materials (e.g., a bonding between copper and copper) and a bonding between dielectric materials (e.g., a bonding between oxide and oxide).

The operating module 80 may be configured to receive powers (or regulated powers) from the electronic components 32 and 34. For example, the operating module 80 may be configured to receive power P3 as shown in FIG. 2. In some arrangements, the electronic components 32 and 34 may provide the operating module 80 with powers at different levels (e.g., 8 V, 6 V, 4 V, 2 V, or less).

In a comparative example, the input and output capacitors are mounted on the same carrier (e.g., the carrier B). In this case, additional electrical connections (e.g., solder balls) are required to be disposed between the carrier A and the carrier B to transmit the power to the input capacitors, which requires an additional area to accommodate said electrical connections. Further, the electrical path between the input capacitors and second stage power module relatively lengthy, leading to increased power loss. In this arrangement, the passive devices 72 may be mounted on the carrier 12 (or the carrier A), and the passive devices 72 may be configured to provide an electrical path conducting the power P2 without passing through the carrier 13. This arrangement can reduce the number of electrical connectors 75, which in turn decreases the surface area (for instance, the surface area along the XY plane) of the electronic device 1a. Additionally, the electrical path for power P2 may be shorter than in the comparative example, further minimizing power loss.

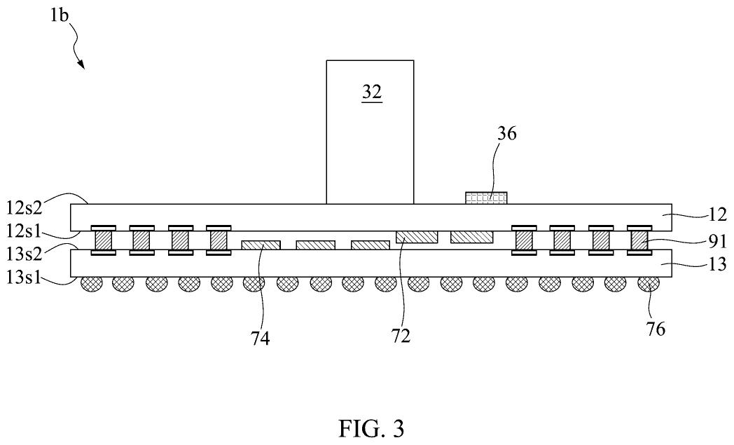

FIG. 3 illustrates a cross-sectional view of an electronic device 1b, in accordance with some arrangements of the present disclosure. The electronic device 1b is similar to the electronic device 1a, differing as follows.

In some arrangements, the electronic device 1b may include conductive elements 91. In some arrangements, the conductive elements 91 may be disposed and electrically connected between the carriers 12 and 13. In some arrangements, the conductive elements 91 may function as a spacer to control or adjust the distance between the carriers 12 and 13. In some arrangements, the conductive elements 91 may include conductive pillars or other suitable elements.

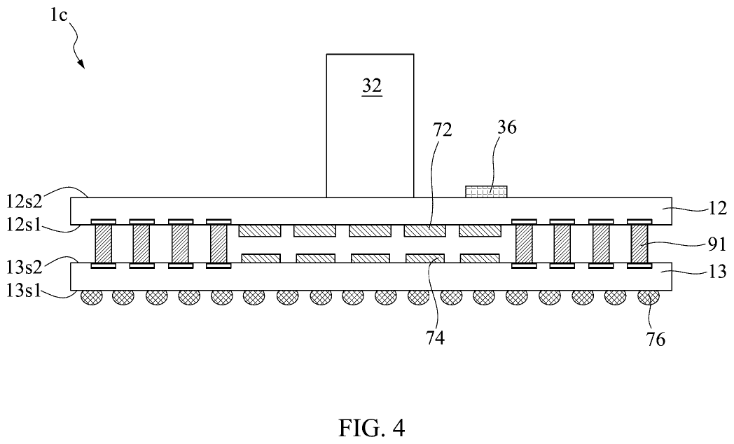

FIG. 4 illustrates a cross-sectional view of an electronic device 1c, in accordance with some arrangements of the present disclosure. The electronic device 1c is similar to the electronic device 1a, differing as follows.

In some arrangements, the passive devices 72 may be free from laterally overlapping the passive devices 74. In some arrangements, the passive devices 72 may vertically overlap the passive devices 74. In this arrangement, the electronic device 1c may feature additional regions on the surface 12s1 of carrier 12, which can accommodate passive devices 72. Similarly, there are extra areas on the surface 13s2 of carrier 13 designated for the placement of passive devices 74. Consequently, this arrangement has the potential to enhance the performance of electronic device 1c.

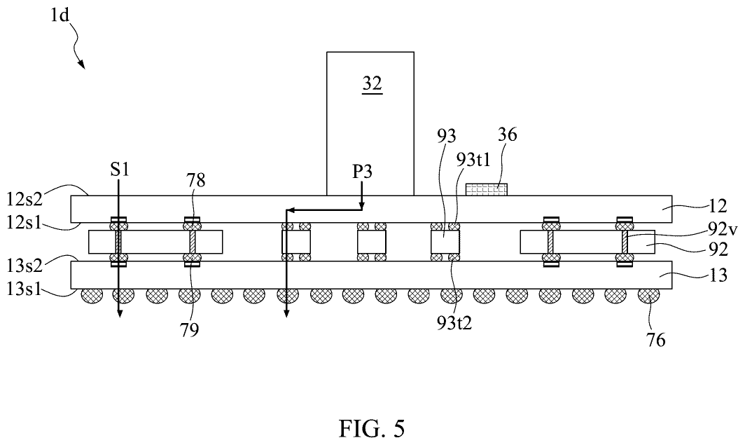

FIG. 5 illustrates a cross-sectional view of an electronic device 1d, in accordance with some arrangements of the present disclosure. The electronic device 1d is similar to the electronic device 1a, differing as follows.

In some arrangements, the electronic device 1d may include an interposer 92. The interposer 92 may be electrically connected between the carriers 12 and 13. In some arrangements, the interposer 92 may be electrically connected to the carrier 12 by electrical connectors 78. In some arrangements, the interposer 92 may be electrically connected to the carrier 13 by electrical connectors 79. The electrical connectors 78 and electrical connectors 79 may include a reflowable material, such as solder balls. In some arrangements, the interposer 92 may be configured to provide an electrical path conducting the signal S1. The interposer 92 may include conductive vias 92v (or through vias) penetrating the interposer 92.

In some arrangements, the electronic device 1d may include passive devices 93. In some arrangements, the passive devices 93 may include input capacitors. In some arrangements, the passive devices 93 may include output capacitors. In some arrangements, the passive devices 93 may have a terminal 93t1 connected to the carrier 12 and a terminal 93t2 connected to the carrier 13. In some arrangements, the carrier 12 may be electrically connected to the carrier 13 through the passive devices 93. In some arrangements, the passive devices 93 may be configured to provide an electrical path conducting the power P3 from the carrier 12 to the carrier 13 without passing through the interposer 92. In some arrangements, a portion of the passive devices 72 and 74 of the electronic devices 1a to 1c may be replaced by the passive devices 93. Further, the electronic device 1d may include conductive elements 12v1 and 12v2 as shown in FIG. 2, which may be configured to electrically connect the electronic component 36 and the passive device 93 or connect the electronic component 32 and the passive device 93. In this arrangement, the interposer 92 may have more terminals configured to transmit signals, which enhances the performance of the electronic device 1d. In this arrangement, each of the electrical connectors 78 and 79 may have a relatively small dimension (e.g., volume or width), and the distance between the conductive vias 92v may be reduced. Therefore, the dimension of the interposer 92 may be reduced to accommodate more components (e.g., passive devices 93) between the carriers 12 and 13.

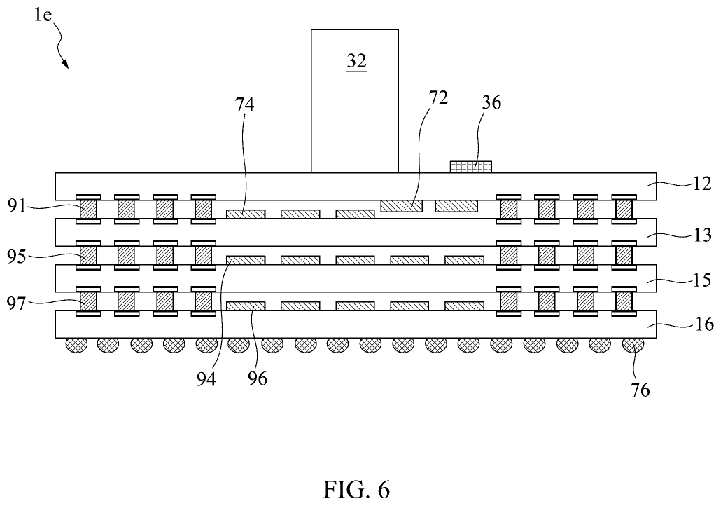

FIG. 6 illustrates a cross-sectional view of an electronic device 1e, in accordance with some arrangements of the present disclosure. The electronic device 1e is similar to the electronic device 1a, differing as follows.

The electronic device 1e may include carriers 15 and 16. Each of the carriers 15 and 16 may include a PCB, FPCB, or other suitable circuit structures. The carrier 15 may be disposed on or under the carrier 13. The carrier 16 may be disposed on or under the carrier 15. The carriers 15 and 16 may be disposed between the carriers 13 and 14 as shown in FIG. 1.

The electronic device 1e may include passive devices 94 and conductive elements 95. The passive devices 94 may be mounted on the carrier 15. The conductive elements 95 may be electrically connected between the carriers 13 and 15. The passive devices 94 may include output capacitors through which the power flows after being transmitted from the electronic component 32 (or electronic component 34). The passive devices 94 may vertically overlap the passive devices 74. The passive devices 94 may vertically overlap the passive devices 72. The conductive elements 95 may include conductive pillars or other suitable elements (e.g., solder balls).

The electronic device 1e may include passive devices 96 and conductive elements 97. The passive devices 96 may be mounted on the carrier 16. The conductive elements 97 may be electrically connected between the carriers 15 and 16. The passive devices 96 may include output capacitors through which the power flows after being transmitted from the electronic component 32 (or electronic component 34). The passive devices 96 may vertically overlap the passive devices 74. The passive devices 96 may vertically overlap the passive devices 72. The conductive elements 97 may include conductive pillars or other suitable elements (e.g., solder balls). The conductive elements 97 may be configured to provide a regulated power from the electronic component 32 (or electronic component 34) to an operating module (e.g., the operating module 80). In some arrangements, a portion of the passive devices 94 and 96 may be replaced by the passive devices 93 as shown in FIG. 5.

In this arrangement, additional passive devices 94 and passive devices 96 may be provided, which improves the performance of the electronic device 1e.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first carrier;
a first converter supported by the first carrier;
a first capacitor supported by the first carrier and configured to transceive a first voltage between the first carrier and the first converter; and
a second carrier disposed under the first carrier and configured to receive a second voltage, different from the first voltage, from the first converter.

2. The electronic device of claim 1, further comprising:
a second capacitor supported by the second carrier,
wherein the first capacitor is closer to the first converter than the second capacitor is.

3. The electronic device of claim 2, wherein the first capacitor and the second capacitor are disposed between the first carrier and the second carrier, and the first capacitor is free from vertically overlapping the second capacitor.

4. The electronic device of claim 2, wherein the second capacitor is spaced apart from the first carrier.

5. The electronic device of claim 2, wherein the first capacitor comprises an input capacitor, and the second capacitor comprises an output capacitor.

6. The electronic device of claim 1, wherein the first capacitor is spaced apart from the second carrier.

7. The electronic device of claim 1, further comprising:
a conductive element configured to transmit the first voltage,
wherein the conductive element is disposed outside the second carrier.

8. The electronic device of claim 1, wherein the first capacitor vertically overlaps the first converter.

9. The electronic device of claim 1, further comprising:
a second converter supported by the first carrier, wherein the second converter is configured to receive the first voltage and generate a third voltage different from the second voltage.

10. An electronic device, comprising:
a first power unit;
a first capacitor configured to transmit a first voltage to the first power unit; and
a second capacitor abutting the first capacitor and configured to transmit a second voltage, different from the first voltage, to a computing unit,
wherein the first capacitor is closer to the first power unit than to the computing unit, and the second capacitor is closer to the computing unit than to the first power unit.

11. The electronic device of claim 10, further comprising:
a first carrier supporting the first power unit,
wherein the first capacitor is mounted on the first carrier, and the second capacitor is spaced apart from the first carrier.

12. The electronic device of claim 11, further comprising:
a second carrier,
wherein the second capacitor is mounted on the second carrier.

13. The electronic device of claim 12, wherein the first capacitor is configured to provide an electrical path conducting the first voltage without passing through the second carrier.

14. The electronic device of claim 13, wherein the second capacitor is configured to provide an electrical path conducting the second voltage passing through the first carrier and the second carrier.

15. The electronic device of claim 13, further comprising:
an electrical connector electrically connecting the first carrier and the second carrier,
wherein the electrical connector is configured to adjust a distance between the first carrier and the second carrier.

16. The electronic device of claim 12, further comprising:
an interposer electrically connecting the first carrier and the second carrier.

17. An electronic device, comprising:
a first carrier;
a converter disposed over the first carrier;
a second carrier disposed under the first carrier; and
an input capacitor disposed between the first carrier and the second carrier and electrically connected to the converter,
wherein the input capacitor is configured to provide an electrical path conducting a power to the converter without passing through the second carrier.

18. The electronic device of claim 17, further comprising:
a first output capacitor and a second output capacitor, wherein the first output capacitor and the second output capacitor are disposed on two opposite sides of the second carrier.

19. The electronic device of claim 17, further comprising:
a first output capacitor, wherein the first output capacitor has a first terminal connected to the first carrier and a second terminal connected to the second carrier.

20. The electronic device of claim 19, wherein the converter is configured to provide a voltage to the second carrier through the first terminal and the second terminal of the first output capacitor.
